(19) United States
(12) Patent Application Publication
(10) Pub. No.: US 2011/0092076 A1
(43) Pub. Date: Apr. 21, 2011

(54) APPARATUS AND METHOD OF VAPOR COATING IN AN ELECTRONIC DEVICE

(75) Inventors: Charles D. Lang, Goleta, CA (US); James Daniel Tremel, Santa Barbara, CA (US); Paul Anthony Sant, Santa Barbara, CA (US); Stephen Sorich, Goleta, CA (US); David K. Flattery, Santa Barbara, CA (US); Gary A. Johansson, Hockessin, DE (US); Jerald Feldman, Wilmington, DE (US); Steven Dale Ittel, Wilmington, DE (US); George Simpson, Kennett square, PA (US)

(73) Assignee: E.I. DU PONT DE NEMOURS AND COMPANY, Wilmington, DE (US)

(21) Appl. No.: 12/993,202

(22) PCT Filed: May 19, 2009
(86) PCT No.: PCT/US09/44502

§ 371 Date: Dec. 27, 2010

Related U.S. Application Data
(60) Provisional application No. 61/054,241, filed on May 19, 2008.

(51) Int. Cl. H01L 21/02; C23C 16/00

(52) U.S. Cl. 438/758; 118/715; 257/E21.002

(57) ABSTRACT

An apparatus and method for vapor phase deposition of a reactive surface area (RSA) material onto a substrate of an electronic device. The vapor phase deposition is conducted at ambient pressures in air, and provides capture of residual vapor to minimize environmental release of RSA and other constituents used in the processing.

### BACKGROUND INFORMATION

1. Field of the Disclosure

This disclosure relates in general to an apparatus and method for making an electronic device. It further relates to the vapor phase coating of a substrate of an electronic device.

2. Description of the Related Art

Electronic devices utilizing organic active materials are present in many different kinds of electronic equipment. In such devices, an organic active layer is sandwiched between two electrodes.

One type of electronic device is an organic light emitting diode (OLED). OLEDs are promising for display applications due to their high power-conversion efficiency and low processing costs. Such displays are especially promising for battery-powered, portable electronic devices, including cell-phones, personal digital assistants, handheld personal computers, and DVD players. These applications call for displays with high information content, full color, and fast video rate response time in addition to low power consumption.

Current research in the production of full-color OLEDs is directed toward the development of cost effective, high throughput processes for producing color pixels. For the manufacture of monochromatic displays by liquid processing, spin-coating processes have been widely adopted (see, e.g., David Braun and Alan J. Heeger, Appl. Phys. Letters 58, 1982 (1991)). However, manufacture of full-color displays requires certain modifications to procedures used in manufacture of monochromatic displays. For example, to make a display with full-color images, each display pixel is divided into three subpixels, each emitting one of the three primary display colors, red, green, and blue. This division of full-color pixels into three subpixels has resulted in a need to modify current processes to prevent the spreading of the liquid colored materials (i.e., inks) and color mixing.

Several methods for providing ink containment are described in the literature. These are based on containment structures, surface tension discontinuities, and combinations of both. Containment structures are geometric obstacles to spreading: pixel wells, banks, etc. In order to be effective these structures must be large, comparable to the wet thickness of the deposited materials. Production of a containment patterns allows high quality, low cost manufacturing of OLED displays via printing with solution processing. The containment pattern is created by patternwise exposure of a layer of reactive surface area (RSA) material to radiation. While the RSA coating can be applied by a liquid or vapor process, the vapor process yields advantages such as precluding handling and disposal of liquid waste.

Continuous processing of vapor coatings is preferred over batch processing for high throughput production. Examples of a continuous process include a linear source evaporator for metalizing a moving plastic sheet, or a linear source evaporator for applying a thin film coating to a flat panel substrate. These processes typically operate under vacuum to prevent oxidation of the coating material, or to enhance the evaporation rate. Operation in air, without a significant vacuum environment, permits lower cost processing in addition to high yields and improved quality.

### SUMMARY

The present application provides an apparatus and method for applying a layer of RSA material in air, at ambient pressures. Some of the advantages include a uniform coating thickness, low waste of RSA material and easily scaled up to larger substrate sizes.

The vapor phase apparatus and method comprise a heated block having at least a first inlet and a first slot exit. The first slot exit is in the geometric shape of a slot or rectangle to cover a wide swath of the substrate. The first slot exit can be up to, or even slightly beyond, the width of the substrate. A porous distribution plate can be used adjacent the first slot exit to provide a uniform distribution of vapor of the RSA material. In addition, the block contains a reservoir in communication with the first entrance and the first slot exit. The reservoir serves to provide a steady stream of the RSA material to the first slot exit. Additional second and third exits can be used for second or third RSA materials, respectively, or as passages for applying a slight vacuum to the coating environment, or any combination thereof. The second exit may be upstream from the first slot exit, and the third exit may be downstream from the first slot exit, with either exit being adjustable between fully open and fully closed positions.

The block can be formed from two or more structures, the first entrance, reservoir and the first slot exit can reside within only one structure or be divided between the two or more structures. RSA material is delivered to the block via a feed line from a holding tank; the tank may be pressurized using air or any inert gas such as nitrogen. A thermally conductive material is advantageous as the material choice for the block, and aluminum being one option for the block material.

The distance from the first slot exit to the substrate defines a first gap, and a second and third gap define the distances from the second and third exit to the substrate. The first gap is typically smaller than either the second or third gap. These gaps are adjustable, as relative motion between the block and the substrate permit adjustment in any one or all of the coordinate axes. In addition, either the block or the substrate may be tilted up to plus or minus 30° from a vector normal to the substrate.

An exhaust treatment can be used to capture RSA material, or other constituents not utilized in the vapor coating process. This exhaust treatment can be accomplished by using one or more condensation devices to capture, and possibly recycle, RSA vapor not deposited on the substrate. In addition, any RSA adhering to the block, especially near the first slot exit, can be removed via any combination of physical scrubbing, heating with vaporization, and subsequent condensation or filtering.

### BRIEF DESCRIPTION OF THE DRAWINGS

FIG. 1 illustrates an electronic device.

FIG. 2 illustrates one embodiment of a vapor phase coating apparatus and method.

FIG. 3 illustrates another embodiment of the vapor phase coating operation and method.

FIG. 4 illustrates one embodiment of a gas distribution plate of the vapor phase apparatus.

### DETAILED DESCRIPTION

### Definitions and Clarification of Terms

The term “active” when referring to a layer or material, is intended to mean a layer or material that exhibits electronic or electro-radiative properties. In an electronic device, an active material electronically facilitates the operation of the device. Examples of active materials include, but are not limited to, materials which conduct, inject, transport, or block a charge, where the charge can be either an electron or a hole, and materials which emit radiation or exhibit a change in concentration of electron-hole pairs when receiving radiation. Examples of inactive materials include, but are not limited to, planarization materials, insulating materials, and environmental barrier materials.

The term “organic electronic device” is intended to mean a device including one or more organic semiconductor layers or materials. An organic electronic device includes, but is not limited to: (1) a device that converts electrical energy into radiation (e.g., a light-emitting diode, light emitting diode display, diode laser, or lighting panel), (2) a device that detects a signal using an electronic process (e.g., a photodetector, a photoconductive cell, a photoresistor, a photoswitch, a phototransistor, a phototube, an infrared (“IR”) detector, or a biosensors), (3) a device that converts radiation into electrical energy (e.g., a photovoltaic device or solar cell), (4) a device that includes one or more electronic components that include one or more organic semiconductor layers (e.g., a transistor or diode), or any combination of devices in items (1) through (4).

The term “reactive surface-active composition” (RSA) is intended to mean a composition that comprises at least one material which is radiation sensitive, and when the composition is applied to a layer, the surface energy of that layer is reduced. Exposure of the reactive surface-active composition to radiation results in the change in at least one physical property of the composition. The term is abbreviated “RSA”, and refers to the composition both before and after exposure to radiation.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### Organic Electronic Device

The process will be further described in terms of its application in an electronic device, although it is not limited to such application.

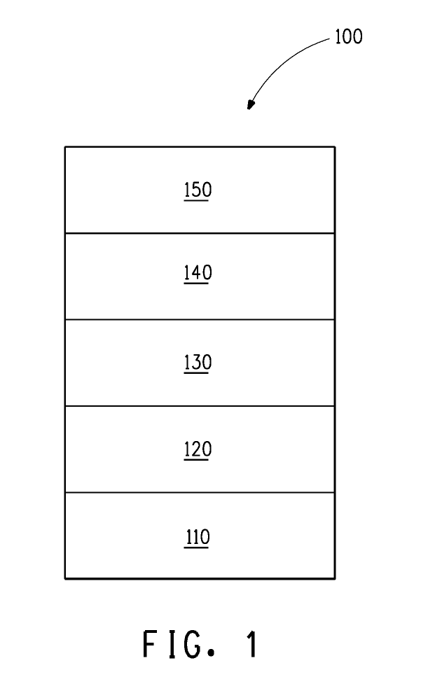

FIG. 1 is an exemplary electronic device, an organic light-emitting diode (OLED) display that includes at least two organic active layers positioned between two electrical contact layers. The electronic device 100 includes one or more layers 120 and 130 to facilitate the injection of holes from the anode layer 110 into the photoactive layer 140. In general, when two layers are present, the layer 120 adjacent the anode is called the hole injection layer or buffer layer. The layer 130 adjacent to the photoactive layer is called the hole transport layer. An optional electron transport layer 150 is located between the photoactive layer 140 and a cathode layer 160 (not shown). Depending on the application of the device 100, the photoactive layer 140 can be a light-emitting layer that is activated by an applied voltage (such as in a light-emitting diode or light-emitting electrochemical cell), a layer of material that responds to radiant energy and generates a signal with or without an applied bias voltage (such as in a photodetector). The device is not limited with respect to system, driving method, and utility mode.

For multicolor devices, the photoactive layer 140 is made up of different areas of at least three different colors. The areas of different color can be formed by printing the separate colored areas. Alternatively, it can be accomplished by forming an overall layer and doping different areas of the layer with emissive materials with different colors. Such a process has been described in, for example, published U.S. patent application 2004-0094768.

In one embodiment, the new process described herein can be used to apply an organic layer (second layer) to an electrode layer (first layer). In one embodiment, the first layer is the anode 110, and the second layer is the buffer layer 120.

In some embodiments, the new process described herein can be used for any successive pairs of organic layers in the device, where the second layer is to be contained in a specific area. In one embodiment of the new process, the second organic active layer is the photoactive layer 140, and the first organic active layer is the device layer applied just before layer 140. In many cases the device is constructed beginning with the anode layer. When the hole transport layer 130 is present, the RSA treatment would be applied to layer 130 prior to applying the photoactive layer 140. When layer 130 was not present, the RSA treatment would be applied to layer 120. In the case where the device was constructed beginning with the cathode, the RSA treatment would be applied to the electron transport layer 150 prior to applying the photoactive layer 140.

In one embodiment of the new process, the second organic active layer is the hole transport layer 130, and the first organic active layer is the device layer applied just before layer 130. In the embodiment where the device is constructed beginning with the anode layer, the RSA treatment would be applied to buffer layer 120 prior to applying the hole transport layer 130.

In one embodiment, the anode 110 is formed in a pattern of parallel stripes. The buffer layer 120 and, optionally, the hole transport layer 130 are formed as continuous layers over the anode 110. The RSA is applied as a separate layer directly over layer 130 (when present) or layer 120 (when layer 130 is not present). The RSA is exposed in a pattern such that the areas between the anode stripes and the outer edges of the anode stripes are exposed.

The layers in the device can be made of any materials which are known to be useful in such layers. The device may include a support or substrate (not shown) that can be adjacent to the anode layer 110 or the cathode layer 150. Most frequently, the support is adjacent the anode layer 110. The support can be flexible or rigid, organic or inorganic. Generally, glass or flexible organic films are used as a support. The anode layer 110 is an electrode that is more efficient for injecting holes compared to the cathode layer 160. The anode can include materials containing a metal, mixed metal, alloy, metal oxide or mixed oxide. Suitable materials include the mixed oxides of the Group 2 elements (i.e., Be, Mg, Ca, Sr, Ba, Ra), the Group 11 elements, the elements in Groups 4, 5, and 6, and the Group 8-10 transition elements. If the anode layer 110 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 110 include, but are not limited to, indium-tin-oxide (“ITO”), aluminum-tin-oxide, gold, silver, copper, and nickel. The anode may also comprise an organic material such as polyaniline, polythiophene, or polypyrrole.

The anode layer 110 may be formed by a chemical or physical vapor deposition process or spin-cast process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include rf magnetron sputtering and inductively-coupled plasma physical vapor deposition (“IMP-PVD”). These deposition techniques are well known within the semiconductor fabrication arts.

Usually, the anode layer 110 is patterned during a lithographic operation. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other processes for patterning that are well known in the art can also be used. When the electronic devices are located within an array, the anode layer 110 typically is formed into substantially parallel strips having lengths that extend in substantially the same direction.

The buffer layer 120 functions to facilitate injection of holes into the photoactive layer and to smoothen the anode surface to prevent shorts in the device. The buffer layer is typically formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The buffer layer 120 can comprise charge transfer compounds, and the like, such as copper phthalocyanine and the tetrathiafulvalene-tetracyanoquinodimethane system (TTF-TCNQ). In one embodiment, the buffer layer 120 is made from a dispersion of a conducting polymer and a colloid-forming polymeric acid. Such materials have been described in, for example, published U.S. patent applications 2004-0102577 and 2004-0127637.

The buffer layer 120 can be applied by any deposition technique. In one embodiment, the buffer layer is applied by a solution deposition method, as described above. In one embodiment, the buffer layer is applied by a continuous solution deposition method.

Examples of hole transport materials for optional layer 130 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino) phenyl]cyclohexane (TAPC); N,N′-bis(4-methylphenyl)-N,N′-bis(4-ethylphenyl)-[1,1′-1-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate. In some embodiments, the hole transport material comprises a cross-linkable oligomeric or polymeric material. After the formation of the hole transport layer, the material is treated with radiation to effect cross-linking. In some embodiments, the radiation is thermal radiation.

The hole transport layer 130 can be applied by any deposition technique. In one embodiment, the hole transport layer is applied by a solution deposition method, as described above. In one embodiment, the hole transport layer is applied by a continuous solution deposition method.

Any organic electroluminescent (“EL”) material can be used in the photoactive layer 140, including, but not limited to, small molecule organic fluorescent compounds, fluorescent and phosphorescent metal complexes, conjugated polymers, and mixtures thereof. Examples of fluorescent compounds include, but are not limited to, pyrene, perylene, rubrene, coumarin, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof.

The photoactive layer 140 can be applied by any deposition technique. In one embodiment, the photoactive layer is applied by a solution deposition method, as described above. In one embodiment, the photoactive layer is applied by a continuous solution deposition method.

Optional layer 150 can function both to facilitate electron injection/transport, and can also serve as a confinement layer to prevent quenching reactions at layer interfaces. More specifically, layer 150 may promote electron mobility and reduce the likelihood of a quenching reaction if layers 140 and 160 would otherwise be in direct contact. Examples of materials for optional layer 150 include, but are not limited to, metal-chelated oxinoid compounds (e.g., Alq₃ or the like); phenanthroline-based compounds (e.g., 2,9-dimethyl-4,7-diphenyl-1,10-phenanthroline (“DDPA”), 4,7-diphenyl-1,10-phenanthroline (“DPA”), or the like); azole compounds (e.g., 2-(4-biphenylyl)-5-(4-t-butylphenyl)-1,3,4-oxadiazole (“PBD” or the like), 3-(4-biphenylyl)-4-phenyl-5-(4-t-butylphenyl)-1,2,4-triazole (“TAZ” or the like); other similar compounds; or any one or more combinations thereof. Alternatively, optional layer 150 may be inorganic and comprise BaO, LiF, Li₂O, or the like.

The cathode 160, is an electrode that is particularly efficient for injecting electrons or negative charge carriers. The cathode layer 160 can be any metal or nonmetal having a lower work function than the first electrical contact layer (in this case, the anode layer 110). In one embodiment, the term “lower work function” is intended to mean a material having a work function no greater than about 4.4 eV. In one embodiment, “higher work function” is intended to mean a material having a work function of at least approximately 4.4 eV.

Materials for the cathode layer can be selected from alkali metals of Group 1 (e.g., Li, Na, K, Rb, Cs), the Group 2 metals (e.g., Mg, Ca, Ba, or the like), the Group 12 metals, the lanthanides (e.g., Ce, Sm, Eu, or the like), and the actinides (e.g., Th, U, or the like). Materials such as aluminum, indium, yttrium, and combinations thereof, may also be used. Specific non-limiting examples of materials for the cathode layer 160 include, but are not limited to, barium, lithium, cerium, cesium, europium, rubidium, yttrium, magnesium, samarium, and alloys and combinations thereof.

The cathode layer 160 is usually formed by a chemical or physical vapor deposition process.

In other embodiments, additional layer(s) may be present within organic electronic devices.

When the device is made starting with the anode side, the RSA treatment step of the new process described herein may be after the formation of the anode 110, after the formation of the buffer layer 120, after the hole transport layer 130, or any combination thereof. When the device is made starting with the cathode side, the RSA treatment step of the new process described herein, may be after the formation of the cathode 160, the electron transport layer 150, or any combination thereof.

The different layers may have any suitable thickness. Inorganic anode layer 110 is usually no greater than approximately 500 nm, for example, approximately 10-200 nm; buffer layer 120, and hole transport layer 130 are each usually no greater than approximately 250 nm, for example, approximately 50-200 nm; photoactive layer 140, is usually no greater than approximately 1000 nm, for example, approximately 50-80 nm; optional layer 150 is usually no greater than approximately 100 nm, for example, approximately 20-80 nm; and cathode layer 160 is usually no greater than approximately 100 nm, for example, approximately 1-50 nm. If the anode layer 110 or the cathode layer 160 needs to transmit at least some light, the thickness of such layer may not exceed approximately 100 nm.

### Apparatus and Process

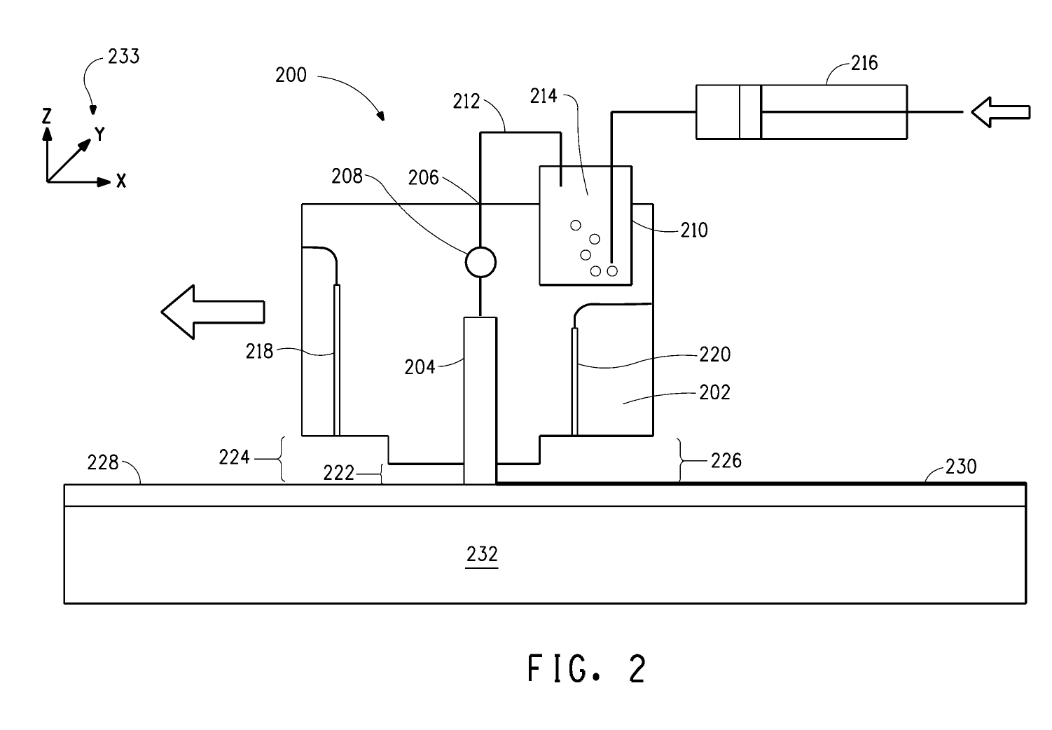

FIG. 2 represents one embodiment of the apparatus 200 and process of the present invention. A block 202 contains a first slot exit 204, a first entrance 206, a reservoir 208, a holding tank 210 and feed line 212. A first RSA material 214 is contained in the holding tank 210, while a pressurization system 216 uses dry air or an inert gas such as nitrogen to pressurize the holding tank 210. A second exit 218 and a third exit 220 are shown upstream, and downstream, respectively, of the first slot exit 204. The second 218 and third 220 exits can be used for second or third RSA materials, respectively, or as passages for applying a slight vacuum to the coating environment, or any combination thereof. In addition, second 218 and third 220 exits are adjustable between fully open and fully closed positions (not shown).

A first gap 222, a second gap 224 and a third gap 226 represent the distance between first slot exit 204, the second exit 218 and the third exit 220 to a substrate 228. In one embodiment the first gap 222 is smaller than either the second 224 or third 226 gap.

Vapor phase first RSA material 214 exits the first slot exit 204 and deposits onto a substrate 228 to produce an RSA layer 230. The substrate 228 is cooled to condense the vapor phase first RSA material 214, one embodiment being the use of a chuck 232 in contact with substrate 228 to provide conductive heat transfer. Another embodiment is the use of gas or vapor cooling (not shown) for convective heat transfer. Relative motion between the block 202 and the substrate 228 can be provided in any of the coordinate axes 233, wherein the block 202 can move relative to a stationary substrate 228, or substrate 228 can move relative to a stationary block 202.

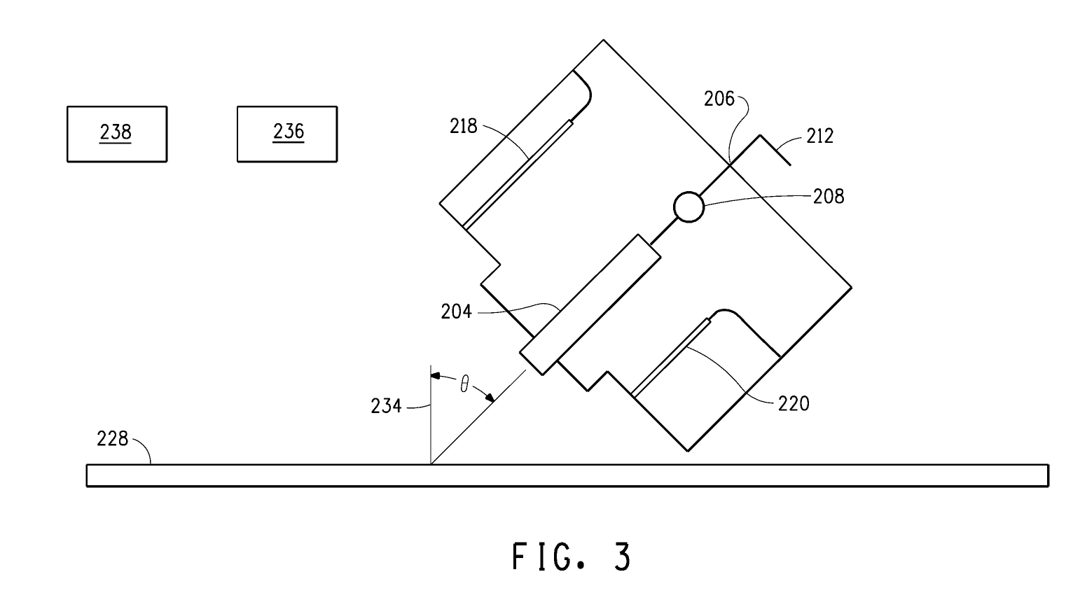

FIG. 3 illustrates one embodiment where the block 202 is tilted with respect to a vector 234 normal to the substrate 228. The angle of tilt is indicated by ⊖, where ⊖ can vary plus or minus 30° from the normal vector 234. In addition, exhaust treatment to remove unused first RSA material 214, in addition to other constituents, can be accomplished by a first condensation device 236 and, optionally, a second condensation device 238.

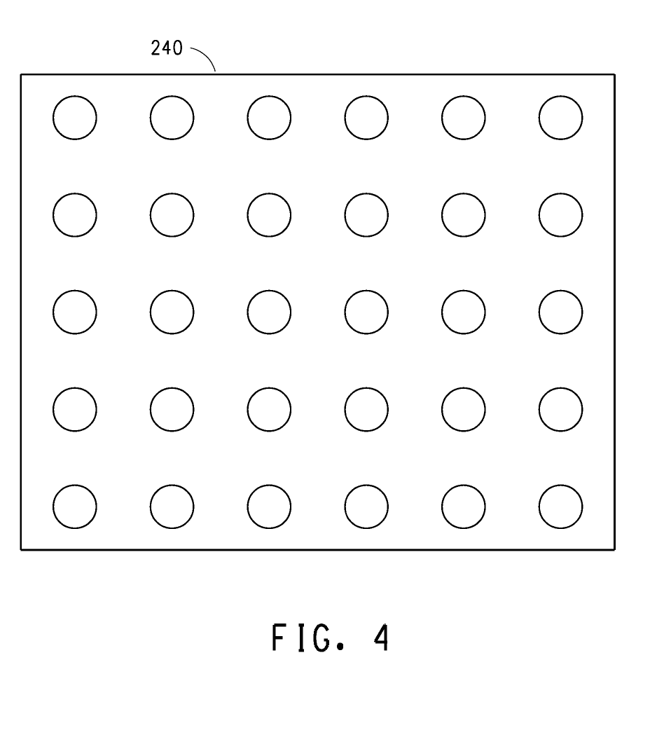

FIG. 4 illustrates one embodiment of a distribution plate 240 located adjacent the first slot exit 204 to evenly distribute vapor for ultimate deposition on the substrate 228.

Process conditions include a coating temperature of 50-150° C. and temperature of substrate 228 of 20-40° C. Operating pressures are of ambient pressure, 1 atmosphere, or even a slight vacuum of about 50 kPa. Coating speeds are of 1-100 mm/s and ranges for first 222 through third 226 gaps of 100-1000 μm. For the slot die exit 204 with dimensions of 400 mm×1.5 mm, gas flow rates of 200-2000 ml/minute at 1 atm and 22° C. are typical. Consumption rates for the first RSA material 214 are approximately 0.2 ml/hr.

In the process provided herein, a first layer is formed, the first layer is treated with the first RSA material 214, the treated first layer is exposed to radiation, and a second layer is formed over the treated and exposed first layer.

In one embodiment, the first layer is the substrate 228. The substrate can be inorganic or organic. Examples of substrates include, but are not limited to glasses, ceramics, and polymeric films, such as polyester and polyimide films.

In one embodiment, the first layer is an electrode. The electrode can be unpatterned, or patterned. In one embodiment, the electrode is patterned in parallel lines. The electrode can be on the substrate 228.

In one embodiment, the first layer is deposited on the substrate 228. The first layer can be patterned or unpatterned. In one embodiment, the first layer is an organic active layer in an electronic device.

The first layer is formed by a vapor deposition technique. In one embodiment, the first layer is deposited by a vapor phase deposition from the heated block 202, having a slot exit 204, with condensation of the first RSA material 214 vapor on the substrate 228 followed by drying. In this case, the first RSA material 214 is pressurized using air or an inert gas (nitrogen, etc.). Relative motion is created between the block and the substrate by moving the substrate relative to a stationary block, or, in the alternative, the block moves relative to a stationary substrate. This relative motion is accomplished in at least one of the principle coordinate axes 233.

The drying step can take place at room temperature or at elevated temperatures, but ambient temperature decreases total process time as the substrate is ready for subsequent operations in completing the electronic device. Temperature ranges are typically 50-150° C., while other temperatures are acceptable so long as the first RSA material 214 and any subsequent materials are not damaged.

The vapor deposition can be coincidental with or subsequent to the formation of the first layer. In one embodiment, the RSA treatment is subsequent to the formation of the first layer. In this embodiment, the RSA is applied as a separate layer overlying, and in direct contact with, the first layer.

In one embodiment, the first RSA material 214 is applied without adding a solvent in the vapor deposition. RSA is heated to above the respective RSA melt temperature to produce the vapor phase. After deposition of the vapor phase RSA, a cooled substrate 228 permits the RSA to phase change to a liquid below its melting point in order to form a second layer over the first layer.

In some embodiments, the RSA treatment comprises a first step of forming a sacrificial layer over the first layer, and a second step of applying an RSA layer over the sacrificial layer. The sacrificial layer is one which is more easily removed than the RSA layer by whatever development treatment is selected. Thus, after exposure to radiation, as discussed below, the RSA layer and the sacrificial layer are removed in either the exposed or unexposed areas in the development step. The sacrificial layer is intended to facilitate complete removal of the RSA layer in the selected areas and to protect the underlying first layer from any adverse affects from the reactive species in the RSA layer.

After the RSA treatment, the treated first layer is exposed to radiation. The type of radiation used will depend upon the sensitivity of the RSA as discussed above. The exposure can be a blanket, overall exposure, or the exposure can be patternwise. As used herein, the term “patternwise” indicates that only selected portions of a material or layer are exposed. Patternwise exposure can be achieved using any known imaging technique. In one embodiment, the pattern is achieved by exposing through a mask. In one embodiment, the pattern is achieved by exposing only select portions with a laser. The time of exposure can range from seconds to minutes, depending upon the specific chemistry of the RSA material used. When lasers are used, much shorter exposure times are used for each individual area, depending upon the power of the laser. The exposure step can be carried out in air or in an inert atmosphere, depending upon the sensitivity of the materials.

In one embodiment, the radiation is selected from the group consisting of ultra-violet radiation (10-390 nm), visible radiation (390-770 nm), infrared radiation (770-10⁶ nm), and combinations thereof, including simultaneous and serial treatments. In one embodiment, the radiation is thermal radiation. In one embodiment, the exposure to radiation is carried out by heating. The temperature and duration for the heating step is such that at least one physical property of the RSA is changed, without damaging any underlying layers of the light-emitting areas. In one embodiment, the heating temperature is less than 250° C. In one embodiment, the heating temperature is less than 150° C.

In one embodiment, the radiation is ultraviolet or visible radiation. The radiation can be applied patternwise, resulting in exposed regions of RSA and unexposed regions of RSA.

In one embodiment, after patternwise exposure to radiation, the first layer is treated to remove either the exposed or unexposed regions of the RSA. Patternwise exposure to radiation and treatment to remove exposed or unexposed regions is well known in the art of photoresists.

In one embodiment, the exposure of the RSA to radiation results in a change in the solubility or dispersibility of the RSA in solvents. When the exposure is carried out patternwise, this can be followed by a wet development treatment. The treatment usually involves washing with a solvent which dissolves, disperses or lifts off one type of area. In one embodiment, the patternwise exposure to radiation results in insolubilization of the exposed areas of the RSA, and treatment with solvent results in removal of the unexposed areas of the RSA.

In one embodiment, the exposure of the RSA to visible or UV radiation results in a reaction which decreases the volatility of the RSA in exposed areas. When the exposure is carried out patternwise, this can be followed by a thermal development treatment. The treatment involves heating to a temperature above the volatilization or sublimation temperature of the unexposed material and below the temperature at which the material is thermally reactive. For example, for a polymerizable monomer, the material would be heated at a temperature above the sublimation temperature and below the thermal polymerization temperature. It will be understood that RSA materials which have a temperature of thermal reactivity that is close to or below the volatilization temperature, may not be able to be developed in this manner.

In one embodiment, the exposure of the RSA to radiation results in a change in the temperature at which the material melts, softens or flows. When the exposure is carried out patternwise, this can be followed by a dry development treatment. A dry development treatment can include contacting an outermost surface of the element with an absorbent surface to absorb or wick away the softer portions. This dry development can be carried out at an elevated temperature, so long as it does not further affect the properties of the originally unexposed areas.

After treatment with the RSA, and exposure to radiation, the first layer has a lower surface energy than prior to treatment. In the case where part of the RSA is removed after exposure to radiation, the areas of the first layer that are covered by the RSA will have a lower surface energy that the areas that are not covered by the RSA.

The thickness of the RSA layer can depend upon the ultimate end use of the material. In some embodiments, the RSA layer is at least 100 Å in thickness. In other embodiments, the RSA layer is in the range of 100-3000 Å; in some other embodiments 1000-2000 Å.

### Reactive Surface-Active (RSA) Composition

The reactive surface-active composition (RSA) is a radiation-sensitive composition. When exposed to radiation, at least one physical property and/or chemical property of the RSA is changed such that the exposed and unexposed areas can be physically differentiated. Treatment with the RSA lowers the surface energy of the material being treated.

In one embodiment, the RSA is a radiation-hardenable composition. In this case, when exposed to radiation, the RSA can become more soluble or dispersable in a liquid medium, less tacky, less soft, less flowable, less liftable, or less absorbable. Other physical properties may also be affected.

In one embodiment, the RSA is a radiation-softenable composition. In this case, when exposed to radiation, the RSA can become less soluble or dispersable in a liquid medium, more tacky, more soft, more flowable, more liftable, or more absorbable. Other physical properties may also be affected.

The radiation can be any type of radiation to which results in a physical change in the RSA. In one embodiment, the radiation is selected from infrared radiation, visible radiation, ultraviolet radiation, and combinations thereof.

Physical differentiation between areas of the RSA exposed to radiation and areas not exposed to radiation, hereinafter referred to as “development,” can be accomplished by any known technique. Such techniques have been used extensively in the photoresist art. Examples of development techniques include, but are not limited to, treatment with a liquid medium, treatment with an absorbant material, treatment with a tacky material, and the like.

In one embodiment, the RSA consists essentially of one or more radiation-sensitive materials. In one embodiment, the RSA consists essentially of a material which, when exposed to radiation, hardens, or becomes less soluble, swellable, or dispersible in a liquid medium, or becomes less tacky or absorbable. In one embodiment, the RSA consists essentially of a material having radiation polymerizable groups. Examples of such groups include, but are not limited to olefins, acrylates, methacrylates and vinyl ethers. In one embodiment, the RSA material has two or more polymerizable groups which can result in crosslinking. In one embodiment, the RSA consists essentially of a material which, when exposed to radiation, softens, or becomes more soluble, swellable, or dispersible in a liquid medium, or becomes more tacky or absorbable. In one embodiment, the RSA consists essentially of at least one polymer which undergoes backbone degradation when exposed to deep UV radiation, having a wavelength in the range of 200-300 nm. Examples of polymers undergoing such degradation include, but are not limited to, polyacrylates, polymethacrylates, polyketones, polysulfones, copolymers thereof, and mixtures thereof.

In one embodiment, the RSA consists essentially of at least one reactive material and at least one radiation-sensitive material. The radiation-sensitive material, when exposed to radiation, generates an active species that initiates the reaction of the reactive material. Examples of radiation-sensitive materials include, but are not limited to, those that generate free radicals, acids, or combinations thereof. In one embodiment, the reactive material is polymerizable or crosslinkable. The material polymerization or crosslinking reaction is initiated or catalyzed by the active species. The radiation-sensitive material is generally present in amounts from 0.001% to 10.0% based on the total weight of the RSA.

In one embodiment, the RSA consists essentially of a material which, when exposed to radiation, hardens, or becomes less soluble, swellable, or dispersible in a liquid medium, or becomes less tacky or absorbable. In one embodiment, the reactive material is an ethylenically unsaturated compound and the radiation-sensitive material generates free radicals. Ethylenically unsaturated compounds include, but are not limited to, acrylates, methacrylates, vinyl compounds, and combinations thereof. Any of the known classes of radiation-sensitive materials that generate free radicals can be used. Examples of radiation-sensitive materials which generate free radicals include, but are not limited to, quinones, benzophenones, benzoin ethers, aryl ketones, peroxides, biimidazoles, benzyl dimethyl ketal, hydroxyl alkyl phenyl acetophone, dialkoxy actophenone, trimethylbenzoyl phosphine oxide derivatives, aminoketones, benzoyl cyclohexanol, methyl thio phenyl morpholino ketones, morpholino phenyl amino ketones, alpha halogennoacetophenones, oxysulfonyl ketones, sulfonyl ketones, oxysulfonyl ketones, sulfonyl ketones, benzoyl oxime esters, thioxanthrones, camphorquinones, ketocoumarins, and Michler's ketone. Alternatively, the radiation sensitive material may be a mixture of compounds, one of which provides the free radicals when caused to do so by a sensitizer activated by radiation. In one embodiment, the radiation sensitive material is sensitive to visible or ultraviolet radiation.

In one embodiment, the RSA is a compound having one or more crosslinkable groups. Crosslinkable groups can have moieties containing a double bond, a triple bond, a precursor capable of in situ formation of a double bond, or a heterocyclic addition polymerizable group. Some examples of crosslinkable groups include benzocyclobutane, azide, oxiran, di(hydrocarbyl)amino, cyanate ester, hydroxyl, glycidyl ether, C1-10 alkylacrylate, C1-10 alkylmethacrylate, alkenyl, alkenyloxy, alkynyl, maleimide, nadimide, tri(C1-4)alkylsiloxy, tri(C1-4)alkylsilyl, and halogenated derivatives thereof. In one embodiment, the crosslinkable group is selected from the group consisting of vinylbenzyl, p-ethenylphenyl, perfluoroethenyl, perfluoroehtenyloxy, benzo-3,4-cyclobutan-1-yl, and p-(benzo-3,4-cyclobutan-1-yl)phenyl.

In one embodiment, the reactive material can undergo polymerization initiated by acid, and the radiation-sensitive material generates acid. Examples of such reactive materials include, but are not limited to, epoxies. Examples of radiation-sensitive materials which generate acid, include, but are not limited to, sulfonium and iodonium salts, such as diphenyliodonium hexafluorophosphate.

In one embodiment, the RSA consists essentially of a material which, when exposed to radiation, softens, or becomes more soluble, swellable, or dispersible in a liquid medium, or becomes more tacky or absorbable. In one embodiment, the reactive material is a phenolic resin and the radiation-sensitive material is a diazonaphthoquinone.

Other radiation-sensitive systems that are known in the art can be used as well.

In one embodiment, the RSA comprises a fluorinated material. In one embodiment, the RSA comprises an unsaturated material having one or more fluoroalkyl groups. In one embodiment, the fluoroalkyl groups have from 2-20 carbon atoms. In one embodiment, the RSA is a fluorinated acrylate, a fluorinated ester, or a fluorinated olefin monomer. Examples of commercially available materials which can be used as RSA materials, include, but are not limited to, Zonyl® 8857A, a fluorinated unsaturated ester monomer available from E.I. du Pont de Nemours and Company (Wilmington, Del.), and 3,3,4,4,5,5,6,6,7,7,8,8,9,9,10,10,11,11,12,12,12-eneicosafluorododecyl acrylate (H₂C═CHCO₂CH₂CH₂(CF₂)₉CF₃) available from Sigma-Aldrich Co. (St. Louis, Mo.).

In one embodiment, the RSA is a fluorinated macromonomer. As used herein, the term “macromonomer” refers to an oligomeric material having one or more reactive groups which are terminal or pendant from the chain. In some embodiments, the macromonomer has a molecular weight greater than 1000; in some embodiments, greater than 2000; in some embodiments, greater than 5000. In some embodiments, the backbone of the macromonomer includes ether segments and perfluoroether segments. In some embodiments, the backbone of the macromonomer includes alkyl segments and perfluoroalkyl segments. In some embodiments, the backbone of the macromonomer includes partially fluorinated alkyl or partially fluorinated ether segments. In some embodiments, the macromonomer has one or two terminal polymerizable or crosslinkable groups.

In one embodiment, the RSA is an oligomeric or polymeric material having cleavable side chains, where the material with the side chains forms films with a different surface energy that the material without the side chains. In one embodiment, the RSA has a non-fluorinated backbone and partially fluorinated or fully fluorinated side chains. The RSA with the side chains will form films with a lower surface energy than films made from the RSA without the side chains. Thus, the RSA can be can be applied to a first layer, exposed to radiation in a pattern to cleave the side chains, and developed to remove the side chains. This results in a pattern of higher surface energy in the areas exposed to radiation where the side chains have been removed, and lower surface energy in the unexposed areas where the side chains remain. In some embodiments, the side chains are thermally fugitive and are cleaved by heating, as with an infrared laser. In this case, development may be coincidental with exposure in infrared radiation. Alternatively, development may be accomplished by the application of a vacuum or treatment with solvent. In some embodiment, the side chains are cleavable by exposure to UV radiation. As with the infrared system above, development may be coincidental with exposure to radiation, or accomplished by the application of a vacuum or treatment with solvent.

In one embodiment, the RSA comprises a material having a reactive group and second-type functional group. The second-type functional groups can be present to modify the physical processing properties or the photophysical properties of the RSA. Examples of groups which modify the processing properties include plasticizing groups, such as alkylene oxide groups. Examples of groups which modify the photophysical properties include charge transport groups, such as carbazole, triarylamino, or oxadiazole groups.

In one embodiment, the RSA reacts with the underlying area when exposed to radiation. The exact mechanism of this reaction will depend on the materials used. After exposure to radiation, the RSA is removed in the unexposed areas by a suitable development treatment. In some embodiments, the RSA is removed only in the unexposed areas. In some embodiments, the RSA is partially removed in the exposed areas as well, leaving a thinner layer in those areas. In some embodiments, the RSA that remains in the exposed areas is less than 50 Å in thickness. In some embodiments, the RSA that remains in the exposed areas is essentially a monolayer in thickness.

It is to be appreciated that certain features are, for clarity, described herein in the context of separate embodiments, may also be provided in combination in a single embodiment. Conversely, various features that are, for brevity, described in the context of a single embodiment, may also be provided separately or in any combination. Further, reference to values stated in ranges include each and every value within that range.

What is claimed is:

1. An apparatus for vapor phase coating of a substrate, the apparatus comprising:
a block having at least a first entrance, a reservoir, a first slot exit, a second exit and a third exit; and
a feed line attached to the first entrance for providing an RSA material to the block;
wherein a first gap is the distance between the first slot exit and the substrate, a second gap is the distance between the second exit and the
substrate and the third gap is the distance between the third exit and the substrate, and the first gap is less than either the second or third gap.

2. The apparatus of claim 1 wherein the block is formed from at least a first and a second structure, wherein the first structure contains the first entrance, the reservoir and the first slot exit.

3. The apparatus of claim 1 wherein the second exit is upstream of the first slot exit and the third exit is downstream of the first slot exit.

4. The apparatus of claim 3 wherein the second and third exits are each adjustable between a fully open and a fully closed state.

5. The apparatus of claim 4 wherein the block orientation is adjustable plus or minus 30 degrees from a vector normal to the surface of the substrate.

7. The apparatus of claim 4 further comprising a vacuum source connected to either or both of the second or third exits.

8. The apparatus of claim 4 further comprising an exhaust treatment comprising a first condensation device.

9. The apparatus of claim 8 further comprising an exhaust treatment comprising a second condensation device.

10. The apparatus of claim 1 wherein a porous distribution plate is located adjacent the first slot exit.

11. The apparatus of claim 1 wherein the block is made of aluminum.

12. A method for vapor phase coating of a substrate, the method comprising:
providing a block, the block comprising at least a first entrance, a reservoir, a first slot exit, a second exit and a third exit;
providing a holding tank for a first reactive surface area (RSA) material;
heating the block to a first temperature and the holding tank to a second temperature;
pressurizing the holding tank;
feeding the first RSA material from the holding tank to the first entrance and into the reservoir moving either the block or the substrate to produce relative motion in at least one of the coordinate axes; and
flowing the RSA material through the first slot exit and onto the substrate.

13. The method of claim 12 further comprising:
flowing a second material through the second exit and onto the substrate.

14. The method of claim 13 wherein the second material is a second RSA material.

15. The method of claim 12 further comprising:
applying a vacuum source connected to either the second or third exits.

16. The method of claim 12 further comprising:
cooling the substrate to condense the first RSA material on the substrate.

17. The method of claim 16 further comprising:
providing an exhaust treatment comprising a first condensation device.

18. The method of claim 17 further comprising:
providing a second condensation device.

19. The method of claim 17 further comprising:
cleaning the block to remove first RSA material to the exhaust treatment.

20. The method of claim 12 further comprising:
providing a porous distribution plate located adjacent the first slot exit.
